(19) United States
(12) Patent Application Publication
(10) Pub. No.: US 2025/0308927 A1
(43) Pub. Date: Oct. 2, 2025

(54) METHODS AND APPARATUSES FOR REMOVING TEMPORARY BONDING MATERIAL

(71) Applicant: Adeia Semiconductor Bonding Technologies Inc., San Jose, CA (US)

(72) Inventors: Guilian Gao, Campbell, CA (US); Gaius Gillman Fountain, JR., Youngsville, NC (US)

(21) Appl. No.: 18/987,957

(22) Filed: Dec. 19, 2024

Related U.S. Application Data
(60) Provisional application No. 63/571,648, filed on Mar. 29, 2024.

(51) Int. Cl. H01L 21/321; H01L 21/683

(52) U.S. Cl. CPC H01L 21/3212; H01L 21/6836

(57) ABSTRACT

Methods and apparatuses to remove temporary bonding material (e.g., residue material, bulk material, a material layer) from surfaces of substrates are disclosed. A first substrate has a thickness of less than about 400 um and comprises a first surface and a second surface opposite the first surface. A temporary bonding material is disposed on the second surface of the first substrate. A method comprises attaching the first substrate to a second substrate such that the first surface of the first substrate is attached to a surface of the second substrate. The method further comprises mechanically scrubbing the temporary bonding material disposed on the second surface of the first substrate with a chemical mechanical polishing (CMP) pad to remove the temporary bonding material from the second surface of the first substrate.

### CROSS-REFERENCE TO RELATED APPLICATION

This application claims the benefit of U.S. Provisional Patent Application No. 63/571,648, filed Mar. 29, 2024, which is hereby incorporated by reference herein in its entirety.

### FIELD

The present disclosure relates to methods and apparatuses for cleaning substrates, and in particular, cleaning temporary bonding material from substrates.

### BACKGROUND

Temporary bonding adhesives may be used for temporary bonding of wafers for thinning and backside processing. After debonding wafers, temporary bonding adhesive residue may remain on a surface of the wafers. The residue may be removed using conventional cleaning techniques that may be suitable for wafers used in a soldering processes. However, wafers used in hybrid bonding processes have higher cleanliness requirement and require more strict conductive feature recess control than a soldering process. Accordingly, there exists a need for improved cleaning methods and apparatuses for removing temporary bond residue.

### SUMMARY

Embodiments herein may provide for methods and apparatuses to remove temporary bonding material (e.g., temporary bonding adhesive, temporary bonding material residue, etc.) from surfaces of substrates (e.g., wafers, dies, etc.). For example, after a substrate is debonded from a carrier substrate (e.g., carrier wafer, carrier die, etc.) a temporary bonding material or residue may remain on the surface of the substrate. In another example, a substrate may have temporary bonding material or layer on the surface of the substrate. The substrate may be a thin substrate of less than about 400 um, 100 um, 50 um, or 20 um in thickness. Methods may include using Chemical Mechanical Polishing (CMP) or mechanical brushing to remove temporary bonding material (e.g., residue material, bulk material, a layer of material) from surfaces of substrates. Apparatuses may include a CMP head (e.g., polishing head component used to press a substrate against a rotating polishing pad) for handling thin substrates or a roller brush (e.g., a roller with CMP pad material covering at least a portion of a surface of a roller) that are used when removing temporary bonding materials from surfaces of substrates. The temporary bonding material may be residue material (e.g., smaller quantity of temporary bonding material), bulk material (e.g., a larger quantity of temporary bonding material), or a layer of temporary bonding material that may be removed from a substrate using CMP or mechanical brushing. In some embodiments, a bulk of the temporary bonding material may be removed from a substrate by mechanical peeling or wet solvent cleaning, and the temporary bonding material is a residue material that is removed from the substrate using CMP or mechanical brushing.

Advantageously, the methods and apparatuses for removing temporary bonding materials (e.g., residue material, bulk material, or layer of material) may provide for high quality bonding surfaces for substrates (e.g., low particle density on the surface, precise control of conductive feature recess). Use of the methods or apparatuses may enable meeting surface cleanliness and conductive feature (e.g., conductive material, metal, Cu) recess control requirements for hybrid bonding, and may be performed prior to hybrid bonding. For example, surface cleanliness requirements may be to only have particles or contaminants less than about 1 micron, or less than 0.5 micron, or less than about 0.25 microns, or less than about 150 nm, or less than about 200 nm, or less than about 100 nm in size. As another example, recess control requirements may be to control a recess of a conductive feature from a field surface of the substrate within less than about 10 nm, or less than about 5 nm, or less than about 20 nm.

A first general aspect includes a method for removing temporary bonding material (e.g., temporary bond adhesive, temporary bonding material residue, etc.) from a first substrate (e.g., wafer, die, etc.). The method includes providing a first substrate having a thickness of less than about 400 microns. The first substrate comprises a first surface and a second surface opposite the first surface. A temporary bonding material is disposed on the second surface of the first substrate. The method further comprises attaching the first substrate to a second substrate (e.g., carrier substrate, carrier wafer) such that the first surface of the first substrate is attached to a surface of the second substrate. The method further comprises mechanically scrubbing the temporary bonding material disposed on the second surface of the first substrate with a chemical mechanical polishing (CMP) pad to remove the temporary bonding material from the second surface of the first substrate.

In some embodiments, the method further comprises using deionized water, with or without surfactants or detergent, and/or a combination thereof without a slurry comprising abrasive particles while mechanically scrubbing. In some embodiments, the method further comprises using a slurry comprising abrasive particles while mechanically scrubbing. The method may further include rotating the CMP pad in an orbital motion while mechanically scrubbing and/or rotating the first substrate while mechanically scrubbing. The method may further include oxygen plasma ashing combined with mechanically scrubbing the second surface of the first substrate. The method may further include, before or after mechanically scrubbing the temporary bonding material disposed on the second surface of the first substrate, plasma ashing the first substrate. In some embodiments, the method may include plasma ashing the first substrate before and/or after mechanically scrubbing the second surface of the first substrate. In some embodiments, any suitable ashing process may be used (e.g., oxygen plasma ashing, fluorine plasma ashing, etc.).

In some embodiments, prior to mechanically scrubbing, the first substrate is bonded to a third substrate with temporary bonding adhesive. The method may further include, prior to mechanically scrubbing, debonding the first substrate from the third substrate (e.g., first carrier wafer). The temporary bonding material disposed on the second surface of the first substrate may comprise temporary bonding adhesive residue.

In some embodiments, the first substrate may be diced after removal of the temporary bond material. The method may further include disposing a protective coating on a mechanically scrubbed second surface of the first substrate, attaching the first substrate to a temporary carrier such that the protective coating on the second surface of the first substrate is attached to a surface of the temporary carrier, and removing the second substrate from the first substrate. In some embodiments, attaching the first substrate to the second substrate comprises attaching the first substrate to the second substrate using double sided tape. Removing the second substrate from the first substrate may comprise removing the double sided tape and the second substrate from the first surface of the first substrate. The method may further include flipping the first substrate such that the first surface of the first substrate is attached to the surface of the temporary carrier, and dicing the first substrate.

In some embodiments, the thickness of the first substrate may be less than about 100 microns, less than about 50 microns, or less than about 20 microns. In some embodiments, the temporary bond material may comprise an organic material or an inorganic material. The temporary bond material may comprise a polymer (e.g., ultraviolet (UV) cured polymer, thermal plastic polymer, polyimide).

A second general aspect includes an apparatus (e.g., CMP head) comprising a holder for securing a tape frame, and an air pressure chamber capable of applying pressure to a substrate (e.g., a wafer, die) disposed on a tape held by the tape frame against a CMP pad. The air pressure chamber may be capable of applying a pressure between about 0.5 PSI to 3 PSI.

A third general aspect includes an apparatus (e.g., roller brush) comprising a roller and a chemical mechanical polishing (CMP) pad material attached to the roller. The roller may be covered, at least partially, by the CMP pad material. The apparatus may further include a holder capable of holding a substrate against the CMP pad material attached to the roller and a dispensing mechanism to deliver DI water, surfactants, detergent, or a CMP slurry to the substrate. In some embodiments, the dispensing mechanism may deliver DI water with or without surfactants or detergent, or a CMP slurry to the substrate.

### BRIEF DESCRIPTION OF THE DRAWINGS

The above and other objects and advantages of the disclosure will be apparent upon consideration of the following detailed description, taken in conjunction with the accompanying drawings, in which:

FIG. 1 schematically illustrates using a CMP pad to remove temporary bonding material from a surface of a substrate, in accordance with embodiments of the present disclosure;

FIG. 2A schematically illustrates side views at different stages of a process flow to illustrate aspects of a method, in accordance with embodiments of the present disclosure;

FIG. 2B schematically illustrates side views at different stages of a process flow to illustrate aspects of a method, in accordance with embodiments of the present disclosure;

FIG. 3 schematically illustrates a side view of a CMP head and method of using of the same, in accordance with embodiments of the present disclosure;

FIG. 4 shows an example process flow, in accordance with embodiments of the present disclosure;

FIG. 5 schematically illustrate views of mechanical roller brushes and methods of using the same, in accordance with embodiments of the present disclosure;

FIG. 6 shows an example process flow, in accordance with embodiments of the present disclosure; and

FIGS. 7A-7B schematically illustrate hybrid bonding, according to some embodiments.

The figures herein depict various embodiments of the disclosure for purposes of illustration only. It will be appreciated that additional or alternative structures, assemblies, systems, and methods may be implemented within the principles set out by the present disclosure.

### DETAILED DESCRIPTION

Embodiments herein may provide for methods and apparatuses for removing contaminants such as temporary bonding materials (e.g., temporary bonding adhesive residues or layers) from a surface of a substrate (e.g., wafer, die). For example, after a substrate is debonded from a carrier substrate (e.g., carrier wafer), and the bulk of the temporary bonding adhesive is removed, a temporary bonding residue may remain. In another example, a substrate may have temporary bonding material or layer on the surface of the substrate. The methods and apparatuses for removing temporary bonding materials (e.g., residue material, bulk material, a layer of material, etc.) may provide for high quality bonding surfaces for substrates (e.g., low particle density on the surface, precise control of conductive feature recess). Use of the methods or apparatuses may enable meeting surface cleanliness and conductive feature (e.g., conductive material, metal, Cu) recess control requirements for hybrid bonding, and may be performed prior to hybrid bonding. The substrate may be used in 3D stacking with DBI bonding or hybrid bonding to other substrates (e.g., wafers, dies, or chips) to create an integrated semiconductor device.

Temporary bonding may be used for manufacturing thin wafers and dies. For example, a wafer or die may be temporarily bonded to a carrier wafer with organic or polymer adhesives.

The wafer or die may be thinned or undergo backside processing. After the wafer is debonded from the carrier wafer and the bulk of the adhesive removed, a temporary bonding material residue may remain on a surface of the wafer. It may be challenging to handle a wafer (e.g., debonded thin wafer) and clean the temporary bonding material residue off the wafer without breakage.

Temporary bonding materials such as organic adhesives may be used for manufacturing of thin wafers and dies. Polymer adhesives may be used for temporary bonding of wafers for thinning and backside processing. Adhesive residue may be left on the device wafer surface after debonding (e.g., to a dicing tape frame). Removal of the bonding adhesive residue may not be satisfactory for a surface that is used in hybrid bonding. For example, surfaces used for hybrid bonding may require higher cleanliness than surfaces used for soldering. Surfaces with conductive features used for hybrid bonding may require more strict conductive feature recess control than surfaces used for non-hybrid bonding applications.

In some approaches, a wet chemical clean (e.g., use of solvents, solvent clean, wet solvent clean) and/or a dry clean (e.g., use of plasma ashing with intensity and duration to cause significant in the conductive feature recess) may be used to clean contaminants such as temporary bonding adhesive residues from substrates. However, wet chemical cleaning and dry cleaning may leave particles on the surface and cause a change in a recess of conductive features on the substrate. Wet chemical cleaning substrates may also cause damage to conductive features (e.g., Cu) on the substrates. The wet chemical cleaning solvents (e.g., organic solvents) used to remove temporary bonding adhesive materials may also be corrosive to the conductive materials. Wet chemical cleaning a substrate to remove temporary bonding adhesive residues may cause conductive features of the substrate to be damaged or have a change in recess and not meet surface cleanliness or conductive feature recess control requirements for hybrid bonding.

The temporary bonding material may be a material (e.g., UV cured polymer) that may be removed by mechanically peeling off the material. Some temporary bonding material residue (e.g., a portion of the temporary bonding material) may remain on the surface after a removed portion of the temporary bonding material is peeled off. The temporary bonding material may be a thermal plastic polymer, and a solvent (e.g., d-limonene) may be used to remove bulk of the material. However, the solvent may etch metal (e.g., copper), the residue removal may be incomplete, and particles may be left on the surface. The temporary bonding material may be a polyimide material, and an excimer laser may be used for debonding. In some approaches, plasma ashing may be used for residue removal. However, the plasma process may attack the metal (e.g., copper) and a tape that supports the substrate (e.g., thin wafer).

Advantageously, the methods and apparatuses described herein may provide for improved cleaning or removal of temporary bonding material. Use of CMP in cleaning or removal of temporary bonding material may achieve desired surface roughness and conductive feature (e.g., metal, Cu) recess on a substrate (e.g., thick or thin wafer or dies bonded to a carrier substrate (e.g., carrier wafer or die). CMP may be used for cleaning substrates after debonding and may be used to remove different types of temporary bonding materials (e.g., residue material, bulk material, layer of material, organic material, inorganic material, etc.) from a wafer surface. A method may include removing temporary bonding residue from a first surface of a substrate (e.g., wafer, die) while the second surface of the substrate is attached to a carrier substrate (e.g., carrier wafer) that may be removed after the first surface is cleaned. An apparatus (e.g., a CMP head, a CMP adaptor plate, etc.) may be used in CMP equipment. The CMP head may be capable of handling thin wafers attached to dicing tape on a tape frame. An apparatus (e.g., roller brush using a CMP pad material) may be used in a mechanical brushing equipment.

As described below, semiconductor substrates herein generally have a “device side,” e.g., the side on which semiconductor device elements are fabricated, such as transistors, resistors, capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active” and “non-active sides” may be used to describe surfaces of material layers or features formed on, in, or through the semiconductor substrate, whether or not the material layers or features are ultimately present in the fabricated or assembled device.

Spatially relative terms are used herein to describe the relationships between elements, such as the relationships between layers and other features described below. Unless the relationship is otherwise defined, terms such as “above,” “over,” “upper,” “upwardly,” “outwardly,” “on,” “below,” “under,” “beneath,” “lower,” and the like are generally made with reference to the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements.

Various embodiments disclosed herein include bonded structures in which two or more elements are directly bonded to one another without an intervening adhesive (referred to herein as “direct bonding,” “direct dielectric bonding,” or “directly bonded”). The resultant bonds formed by this technique may be described as “direct bonds” and/or “direct dielectric bonds.” In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (first) nonconductive feature directly bonded to another (second) nonconductive feature, and ii) at least one (first) conductive feature directly bonded to another (second) conductive feature, without any intervening adhesive. The resultant bonds formed by this technique may be described as “hybrid bonds” and/or “direct hybrid bonds.” In some hybrid bonding embodiments, there are many first conductive features, each directly bonded to a second conductive feature, without any intervening adhesive. In some embodiments, nonconductive features on the first element are directly bonded to nonconductive features of the second element at room temperature without any intervening adhesive, which is followed by bonding of conductive features of the first element directly bonded to conductive features of the second element via annealing at slightly higher temperatures (e.g., >100° C., >200°° C., >250° C., >300° C., etc.).

Direct bonding may include direct dielectric bonding techniques as described herein, and may give rise to direct dielectric bonds. Hybrid bonding may include hybrid bonding techniques as described herein, and may give rise to direct hybrid bonds.

Hybrid bonding methods described herein generally include forming conductive features in the dielectric surfaces of the to-be-bonded substrates, activating the surfaces to open chemical bonds in the dielectric material, and terminating the surfaces with a desired species. In some embodiments, activating the surface may weaken chemical bonds in the dielectric material. Activating and terminating the surfaces with a desired species may include exposing the surfaces to radical species formed in a plasma. In some embodiments, the plasma is formed using a nitrogen-containing gas, e.g., N₂, or forming gas and the terminating species includes nitrogen and hydrogen. In some embodiments, the surfaces may be activated using a wet cleaning process, e.g., by exposing the surfaces to aqueous solutions. In some embodiments, the aqueous solution is tetramethylammonium hydroxide diluted to a certain degree or percentage. In some embodiments, an aqueous solution may be ammonia. In some embodiments, the plasma is formed using a fluorine-containing gas, e.g., fluorine gas or helium containing a small amount of fluorine and/or nitrogen such as about 10% or less by volume, 9% or less, 8% or less, 7% or less, 6% or less, 5% or less, 4% or less, 3% or less, 2% or less, for example 1% or less.

Typically, the hybrid bonding methods further include aligning the substrates, and contacting the activated surfaces to form direct dielectric bonds. After the dielectric bonds are formed, the substrates may be heated to a temperature between 50° C. to 150° C. or more, or of 150° C. or more and maintained at the elevated temperature for a duration of about 1 hour or more, such as between 8 and 24 hours, to form direct metallurgical bonds between the metal features.

As used herein, the term “substrate” means and includes any workpiece, wafer, panel, or article that provides a base material or supporting surface from which or upon which components, elements, devices, assemblies, modules, systems, or features of the devices described herein may be formed. The term substrate also includes display substrates such as glass panels or “semiconductor substrates” that provide a supporting material upon which elements of a semiconductor device are fabricated or attached, and any material layers, features, electronic devices, and/or passive devices formed thereon, therein, or therethrough. For ease of description elements, features, and devices formed therefrom are referred to in the singular or plural but should be understood to describe both singular and plural, e.g., one or more, unless otherwise noted.

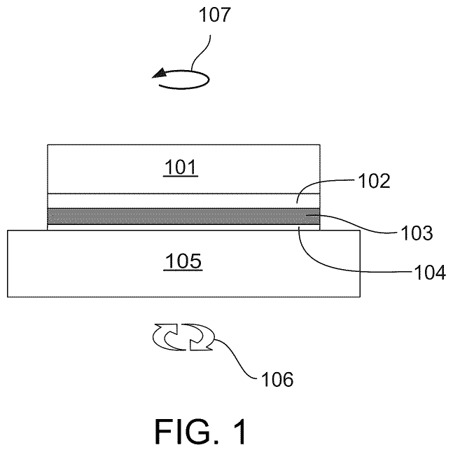

FIG. 1 schematically illustrates using a CMP pad 105 to remove temporary bonding material 104 (e.g., temporary bonding residue) from a surface of a substrate (e.g., first substrate 103), in accordance with embodiments of the present disclosure. A method for cleaning a substrate (e.g., first substrate 103) may include mechanically scrubbing the temporary bonding material 104 on the first substrate 103. The CMP pad 105 may be rotated 106 (e.g., in a circular rotation, orbital rotation, or off-center rotation) while mechanically scrubbing. The first substrate 103 attached to the second substrate 101 (e.g., carrier substrate, second carrier substrate) with double sided tape 102 may be rotated 107 (e.g., in a circular rotation, orbital rotation, or off-center rotation) while mechanically scrubbing. In some embodiments, only the CMP pad 105 is rotated 106 for mechanically scrubbing. In some embodiments, only the first substrate 103 is rotated 107 for mechanically scrubbing. In some embodiments, both the CMP pad 105 is rotated 106 and the first substrate 103 is rotated 107 for mechanically scrubbing. The CMP pad 105 and first substrate 103 may be rotated independently of each other or may rotated in combination.

In some embodiments, the first substrate 103 may be mechanically scrubbed without using a slurry comprising abrasive particles. The first substrate 103 may be mechanically scrubbed with water (e.g., deionized water), with and without surfactants or detergents, a slurry comprising abrasive particles, and/or any combination thereof using the CMP pad 105. For example, water (e.g., deionized water), with and without surfactants or detergents, a slurry comprising abrasive particles, and/or any combination thereof may be dispensed while mechanically scrubbing the first substrate 103.

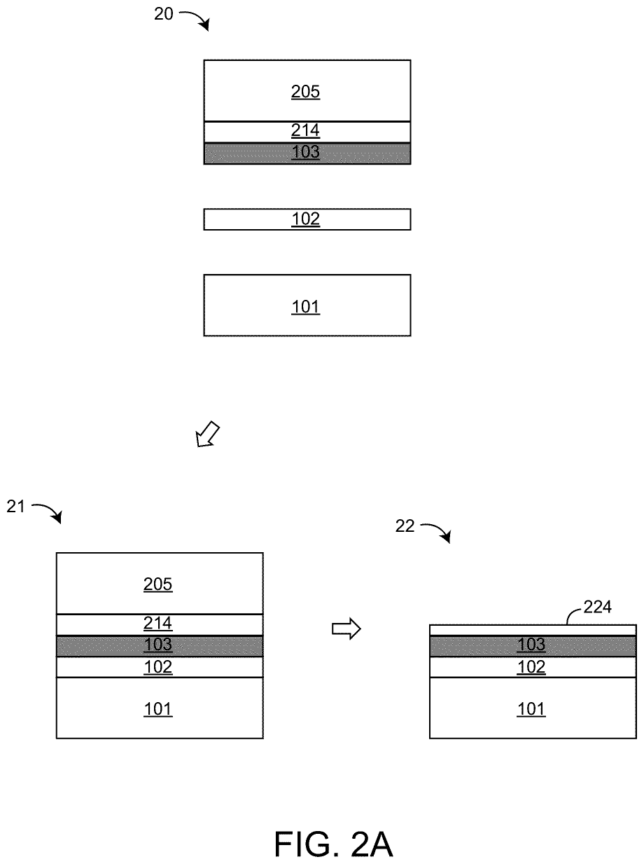

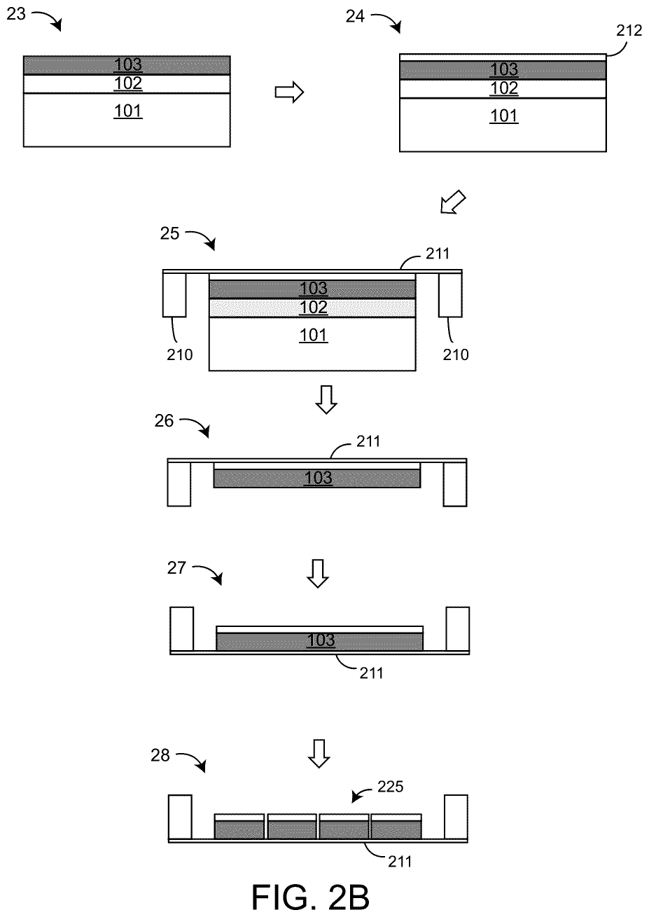

Mechanically scrubbing the first substrate 103 may remove the temporary bonding material 104 from a surface of the first substrate 103 (e.g., as shown in block 23 of FIG. 2A). In some embodiments, mechanically scrubbing the first substrate 103 may remove contaminants or particles from a surface of the first substrate 103. In some embodiments, mechanically scrubbing the first substrate 103 may provide a planarized surface of the first substrate 103. For example, a recess of conductive features disposed in a dielectric layer of the substrate may be controlled using mechanical scrubbing with a CMP pad 105.

The temporary bonding material 104 may be an organic or inorganic material. The temporary bonding material 104 may be a temporary bonding adhesive (e.g., adhesive residue, bulk adhesive, layer of adhesive, etc.). The temporary bonding adhesive may be a material that may tolerate or withstand temperatures up to about 250° C. or to about 400° C., and may be a UV curable adhesive, an organic compound, and/or a material similar to polyimide. The temporary bonding material 104 is disposed on a first surface of a first substrate 103. In some embodiments, the temporary bonding material 104 is a residue remaining on a surface of the first substrate 103 after de-bonding the first substrate 103 from a carrier substrate (e.g., carrier wafer, carrier die, etc.). For example, the temporary bonding material 104 may be the temporary bonding residue 224 as shown in block 22 of FIG. 2A. In some embodiments, the temporary bonding material 104 may be a coating or layer on the surface of the substrate. For example, the temporary bonding material 104 may be the temporary bonding layer 214 disposed on first substrate 103 as shown in block 20 of FIG. 2A (e.g., without being attached to the third substrate 205).

The first substrate 103 may be a wafer or die and comprises a first surface and a second surface opposite the first surface. The first substrate 103 may be a semiconductor substrate comprising any suitable materials (e.g., semiconductor materials, dielectric materials, conductive materials) such as those mentioned in the present disclosure. The first substrate 103 may be a thin or a thick substrate. A thin substrate may be about 10 microns to 500 microns in thickness. A thin substrate may be less than about 400 microns in thickness, less than about 500 microns in thickness, or less than about 50 microns in thickness. A thick substrate may have a thickness about 500-700 microns, greater than about 500 microns, or greater than about 700 microns.

In some embodiments, the first substrate 103 is a thin substrate. A thin substrate may be supported by a thick substrate (e.g., for ease of handling, or to prevent breakage of the thin substrate). A thin substrate may be attached to a carrier substrate during processing (e.g., backside processing, wafer thinning process, CMP process). A carrier substrate (e.g., second substrate 101 of FIG. 1, third substrate 205 of FIG. 2A) may be a thick substrate. During mechanical scrubbing of the first substrate 103, the first substrate may be attached to the second substrate 101 (e.g., carrier substrate) for support. The first substrate 103 may be attached to the second substrate 101 (e.g., carrier wafer, second carrier wafer) by double sided tape 102. In some embodiments, the first substrate 101 may be an 8 inch wafer. In some embodiments, any suitable adhesive or tape may be used in place of the double sided tape 102 to attach the first substrate 103 to the second substrate 101.

FIG. 2A shows an example method of attaching a substrate (e.g., first substrate 103) to a second carrier substrate (e.g., second substrate 101) and debonding the substrate from a first carrier substrate (e.g., third substrate 205). At block 20, a method comprises providing a first substrate 103 attached to a third substrate 205 (e.g., first carrier substrate) with a temporary bonding layer 214. For example, a first surface of the first substrate 103 may be attached to a third substrate 205 (e.g., first carrier wafer) using temporary bonding adhesive. The temporary bonding adhesive may withstand high temperature, and the first substrate 103 may have been processed with a backside process, wafer thinning process. The temporary bonding layer 214 may comprise a temporary bonding material similar to that described above in relation to FIG. 1. The method further comprises providing double sided tape 102 and providing a second substrate 101 (e.g., second carrier substrate).

At block 21, the method comprises attaching the substrate 103 to a second carrier substrate 101 using double sided tape 102. For example, the substrate 103 may be mounted on the substrate 101 using double sided tape 102 or any suitable adhesive layer. The first substrate 103 may have a second surface opposite the first surface that is attached to a second substrate 101 using double sided tape 102. The second substrate 101 may not be used in high temperature processing but may be used for handling the first substrate 103.

At block 22, the method comprises debonding the first substrate 103 from the third substrate 205 (e.g., second carrier substrate). The third substrate 205 may be removed or debonded from the thin wafer (e.g., first substrate 103) by laser debonding, thermal debonding, mechanical debonding, etc. A temporary bonding residue 224 (e.g., portion of the temporary bonding layer 214) may remain on a first surface of the first substrate 103 after debonding the first substrate 103 from the third substrate 205. The method may include using a CMP process (e.g., as described in relation to FIG. 1) to remove the temporary bonding residue 224.

FIG. 2B shows an example method to dice the substrate after removing the temporary bond material (e.g., temporary bond material 104 as shown in FIG. 1). The temporary bonding material may be a temporary bonding layer 214 or a temporary bonding residue 224.

At block 23, the method includes removing temporary bonding material from the first surface of the first substrate 103. A temporary bonding residue 224 or temporary bonding layer 214 may be removed. In some embodiments, the first surface of the first substrate 103 may be mechanically scrubbed or cleaned (e.g., without particles or contaminants of a certain size). In some embodiments, a first surface of the first substrate 103 may be planarized such that conductive features in the first substrate 103 is within a recess requirement for hybrid bonding.

At block 24, the method includes depositing a protective coating 212 (e.g., protective layer) to the cleaned or mechanically scrubbed first surface of the first substrate 103. The protective coating 212 may be photoresist. The protective coating 212 may be a low-temperature polymer that may be dissolved in solvent or a basic solution.

At block 25, the method includes attaching the first substrate 103 to a holder or a temporary carrier (e.g., debonding chuck, tape frame, dicing tape frame). In some embodiments, the holder or temporary carrier comprises a tape 211 and a tape frame 210. The first substrate 103 may be mounted to a tape 211 (e.g., single sided tape, dicing tape, adhesive tape) held by a tape frame 210 such that the protective coating 212 on the first substrate 103 faces the tape 211.

At block 26, the method may include removing the double sided tape 102 and second substrate 101 from the first substrate 103. The double sided tape 102 may be removed from a second surface of the first substrate 103.

At block 27, the method may include flipping the first substrate 103 such that the second surface of the first substrate faces the tape 211 and a surface of the protective coating 212 is exposed. In some embodiments, flipping the first substrate 103 may be performed by transferring the first substrate 103 to another holder (e.g., another tape and tape frame).

At block 28, the method includes dicing the first substrate 103. For example, the first substrate 103 and the protective coating 212 may be diced. The protective coating 212 may keep the surface clean from particles, such as those generated during dicing. The protective coating 212 may be removed after dicing and the diced substrate (e.g., dies 225) may be bonded.

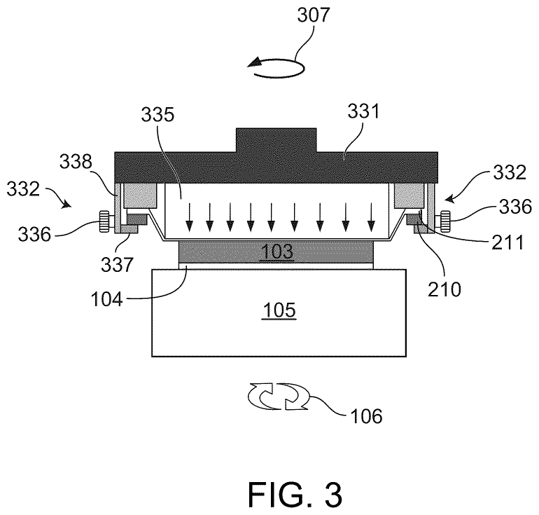

FIG. 3 shows using a CMP pad 105 to remove temporary bonding material 104 on a substrate 103, in accordance with embodiments of the present disclosure. FIG. 3 shows an apparatus comprising a CMP head 331 or a tape frame adaptor capable of holding a tape frame that may be part of CMP equipment or tool. The CMP head 331 may hold a substrate 103 mounted on a temporary carrier (e.g., tape 211 and tape frame 210) and apply a uniform pressure to the back of the substrate 103 to press a substrate (e.g., substrate 103 with temporary bonding material 104) against a CMP pad 105 during cleaning or mechanical scrubbing a surface of the substrate.

The substrate 103 is attached to a temporary carrier or holder comprising a tape 211 and a tape frame 210. The tape 211 may serve as a temporary adhesive layer that holds the substrate 103 in place during one or more manufacturing steps. For example, tape 211 may be used as a membrane to support a substrate 103 for dicing, backside processing, or backgrinding. Tape 211 may be used as a membrane to support a substrate 103 and to generate pressure against a CMP pad 105. The temporary bonding material 104 is disposed on the first surface of the substrate 103, and the second surface of the substrate 103 is facing the tape 211 (e.g., single sided tape, dicing tape, adhesive tape, etc.). In some embodiments, a thin substrate may be attached to tape of a tape frame and CMP equipment may handle the thin substrate without the thin substrate being attached to a carrier substrate (e.g., thick substrate).

The CMP head 331 comprises a holder 332 to hold the temporary carrier (e.g., tape frame 210 and tape 211 on which the substrate 103 is attached). The holder 332 may comprise a clamping mechanism with clamps on a top and bottom side of the tape frame 210 and screw to tighten or release the clamps. In some embodiments, any suitable mechanism (e.g., toggle clamp, magnets, vacuum, etc.) may be used for holding the temporary carrier (e.g., tape frame 210 and tape 211). The clamping mechanism for CMP head 331 may use a similar clamping mechanism for wafer grinding on tape or a tape frame. In some embodiments, a porous vacuum chuck may hold the tape frame 210 and a pressurized bladder (e.g., flexible membrane filled with pressurized air) may be used. In some embodiments, a clamping mechanism may comprise a frame securing structure 338 and a screw 336, and the screw 336 may be rotated to secure or to release the tape frame 210 (e.g., dicing frame) to the frame securing structure 338. The frame securing structure 338 may comprise a frame (e.g., larger frame than tape frame 210) to surround a dicing frame (e.g., tape frame 210). In some embodiments, the frame securing structure comprises one or more frame securing pads 337 (e.g., to hold portions of the dicing frame to secure the dicing frame).

The CMP head 331 comprises an air pressure chamber 335 capable of applying pressure (e.g., air pressure) to the tape 211 and the substrate 103 against the CMP pad 105. In some embodiments, the pressure applied may be enough to clean the surface to remove the temporary bonding material 104 without removal of substrate material (e.g., any suitable substrate material such as semiconductor material, dielectric material, conductive material, etc.). The CMP head 331 may be capable of applying a pressure of about 0.5 to 3 PSI. The CMP head 331 may apply pressure for about 1 minute or less, about 5 minutes or less, or about thirty seconds or less to clean the substrate 103 (e.g., wafer). In some embodiments, a method may include polishing a first surface of the substrate 103.

A method for cleaning a substrate 103 may include mechanically scrubbing the temporary bonding material 104 on the first substrate 103. The CMP pad 105 may be rotated 106 (e.g., in a circular rotation, orbital rotation, or off-center rotation) during cleaning of the substrate 103 (e.g., mechanically scrubbing the temporary bonding material 104). The CMP head 331 may be rotated 307 (e.g., in a circular rotation, orbital rotation, or off-center rotation) during cleaning of the substrate 103 (e.g., mechanically scrubbing the temporary bonding material 104). The rotation 307 is similar to the rotation 107 as described in relation to FIG. 1 except the rotation 307 is applied to the CMP head 331 holding the substrate 103 instead of a second substrate 101 attached to the first substrate 103.

In some embodiments, only the CMP pad 105 is rotated 106 for mechanically scrubbing. In some embodiments, only the CMP head 331 holding the substrate 103 is rotated 107 for mechanically scrubbing. In some embodiments, both the CMP pad 105 is rotated 106 and CMP head 331 holding the substrate 103 is rotated 107 for mechanically scrubbing. The CMP pad 105 and the CMP head 331 holding the substrate 103 may be rotated independently of each other or may rotated in combination.

In some embodiments, the first substrate 103 may be mechanically scrubbed without using a slurry comprising abrasive particles. The first substrate 103 may be mechanically scrubbed with water (e.g., deionized water), with and/or without surfactants or detergent, a slurry comprising abrasive particles, and/or any combination thereof using the CMP pad 105. For example, water (e.g., deionized water), with and/or without surfactants or detergent, a slurry comprising abrasive particles, and/or any combination thereof may be dispensed while mechanically scrubbing the first substrate 103.

Mechanically scrubbing the first substrate 103 may remove the temporary bonding material 104 from a surface of the first substrate 103 (e.g., as shown in block 23 of FIG. 2A). In some embodiments, mechanically scrubbing the first substrate 103 may remove contaminants or particles from a surface of the first substrate 103. In some embodiments, mechanically scrubbing the first substrate 103 may provide a planarized surface of the first substrate 103. For example, a recess of conductive features disposed in a dielectric layer of the substrate may be controlled using mechanical scrubbing with a CMP pad 105.

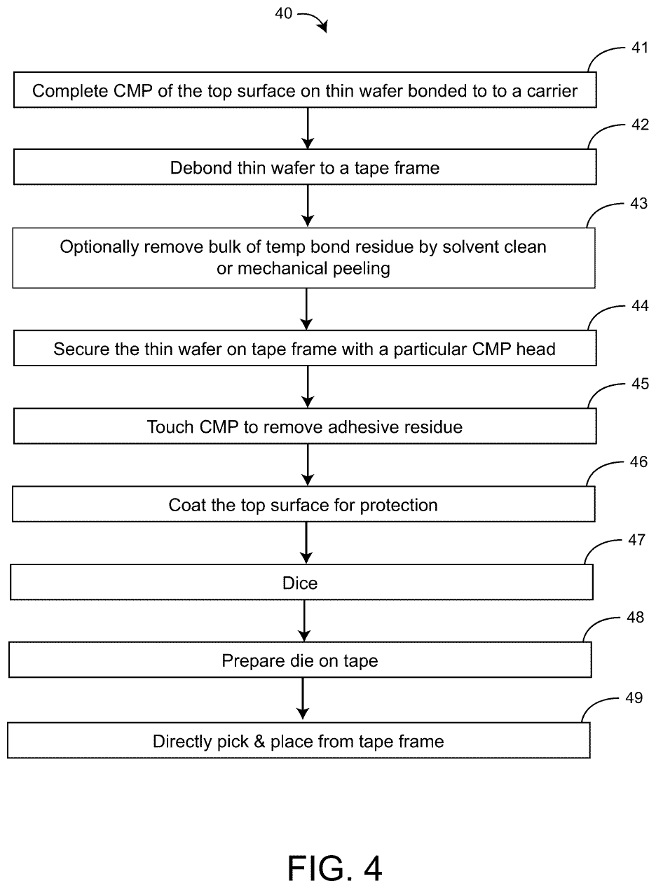

FIG. 4 shows an example method 40, in accordance with embodiments of the present disclosure. In some embodiments, the method 40 may be used in relation to the apparatus shown in FIG. 3.

At block 41, the method 40 may include completing CMP of the top surface of a thin wafer bonded to a carrier. For example, a thin wafer (e.g., substrate 103) may be bonded to a carrier (e.g., substrate 205) using temporary bonding adhesive (e.g., temporary bonding layer 214 as shown in block 20 of FIG. 2A). A bottom surface of the thin wafer (e.g., second surface of substrate 103) may be attached to a surface of the carrier and a top surface (e.g., first surface of substrate 103) may be exposed. The top surface of the wafer may be chemically mechanically polished.

At block 42, the method 40 may include debonding a thin wafer to a tape frame. For example, the thin wafer (e.g., substrate 103) may be debonded from the carrier wafer (e.g., substrate 205) and attached to the tape 211 of the tape frame 210. Temporary bonding material 104 (e.g., temporary bonding material residue) may remain or be disposed on a surface of the thin wafer after debonding.

At block 43, the method 40 may include optionally removing the bulk of the temporary bond residue by solvent clean or mechanical peeling. The method may include removing a larger portion of temporary bond residue (e.g., temporary bonding material 104) using solvent clean or mechanical peeling. A smaller portion of the temporary bond residue may remain on a surface of the thin wafer (e.g., first surface of substrate 103).

In some embodiments, the method 40 may not include removing the bulk of temporary bond residue by solvent clean. For example, the method 40 may proceed directly to block 44 after block 42.

At block 44, the method 40 may include securing the thin wafer on the tape frame with a particular CMP head. For example, the particular CMP head may be the CMP head 331 as shown in FIG. 3. The method 40 may include attaching the thin wafer (e.g., substrate 103) to a tape 211 attached to the tape frame 210.

At block 45, the method 40 may include using touch CMP to remove adhesive residue on the thin wafer. Touch CMP may refer to low-pressure CMP (e.g., mechanically scrubbing with the CMP pad 105 as shown in FIG. 3) which may not remove any or much material of the thin wafer (e.g., substrate 103) and remove only the contaminants (e.g., temporary bonding material 104). Touch CMP may not be used with a slurry, and touch CMP may be used with water, with or without surfactants or detergent.

At block 46, the method 40 may include coating the top surface for protection. For example, the top surface (e.g., first surface of substrate 103) cleaned at block 45 may be coated with photoresist (e.g., protective coating 212 as shown in block 24 of FIG. 2B) to protect the top surface (e.g., surface that is used later for bonding) during dicing the thin wafer (e.g., substrate 103).

At block 47, the method 40 may include dicing the thin wafer. For example, the thin wafer (e.g., substrate 103) with the protective coating may be diced (e.g., as shown in block 28 of FIG. 2B).

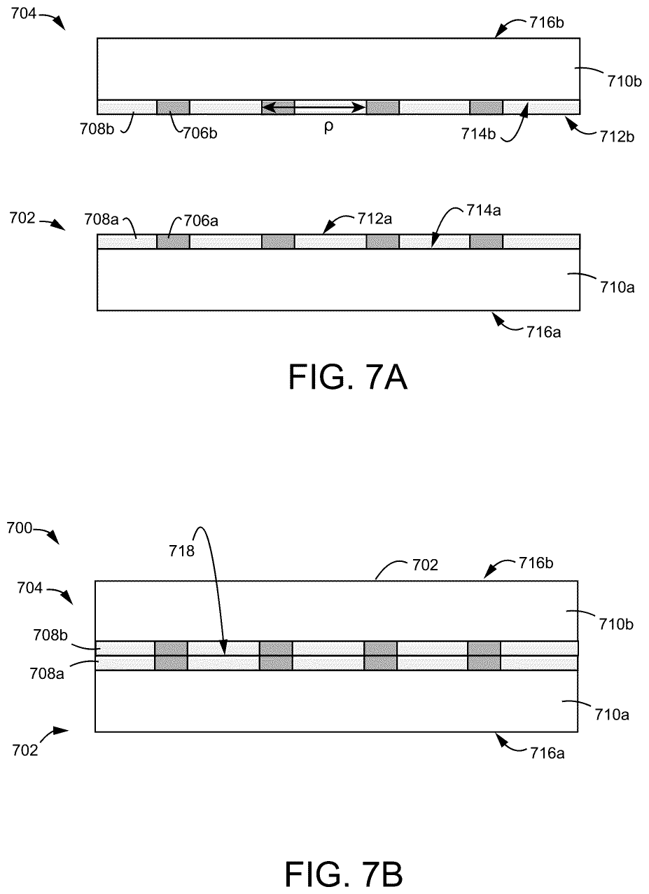

At block 48, the method 40 may include die on tape preparation. For example, the preparation may be cleaning off the protective coating and preparing the surface to be bonded. The method may include stripping the protective coating, rinsing with DI water, and optionally activating the surface to be bonded. Examples of preparing a surface to be bonded can be found in the description of FIGS. 7A-7B.

At block 49, the method 40 may include directly picking and placing dies from the tape frame. For example, a cleaned die (e.g., die 225 with protective coating 212 removed) may be picked from the tape 211 and placed on another substrate (e.g., substrate to be directly bonded, hybrid bonded).

In some embodiments, different types of CMP processes may be used. The pressure for CMP may be about 0.5 to 3 PSI. A CMP head (e.g., CMP head 331) may put pressure on the tape 211. The pressure for back grinding a wafer (e.g., substrate 103) may be higher or much higher, and backgrinding a wafer may be done on a tape frame (e.g., substrate 103 attached to tape 211 on tape frame 210). The adhesive for a UV dicing tape (e.g., tape 211) may be strong enough for CMP, and adhesion after CMP may be greatly reduced by UV exposure. An orbital CMP setup may be used.

In some embodiments, a CMP apparatus may comprise a round flat platen covered by a pad (e.g., CMP pad 105) which makes contact with a wafer (e.g., substrate 103) and cleans it using a rotational motion. In some embodiments, an orbital polisher type of CMP apparatus may be used, in which an orbital motion or an off-center rotation or movement of the pad (e.g., CMP pad 105) cleans a contacted wafer. In some embodiments, the wafer (e.g., substrate 103) is rotated independently along with the cleaning pad (e.g., CMP pad 105). In some embodiments, a rotary polisher type of CMP apparatus is used, in which the wafer (e.g., substrate 103) is facing upwards, and a smaller rotating head polishes the top surface of the wafer.

In some embodiments, a CMP slurry may be used. CMP slurries may comprise particles (e.g., nano-sized abrasive powder) which provide mechanical abrasion to remove material. Use of a CMP slurry may flatten topographic features and improve planarization of a surface. In some embodiments, a CMP slurry may be poured on a pad (e.g., CMP pad 105). In some embodiments, CMP slurry may be introduced onto the wafer through holes in a pad (e.g., CMP pad 105). For example, a rotating head may be covered by a perforated pad through which CMP slurry is introduced onto the wafer. In some embodiments, a cleaning solution or water may be used instead of a CMP slurry.

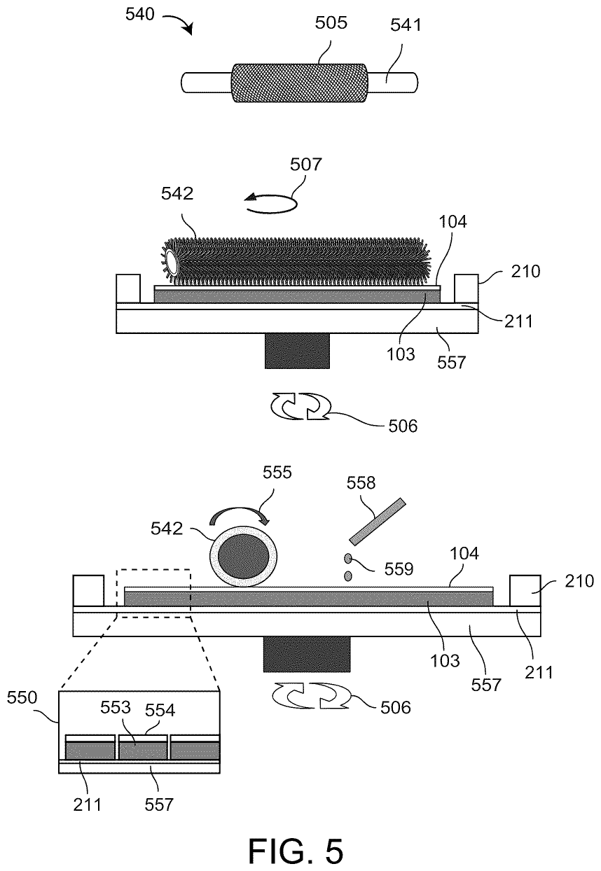

FIG. 5 shows an examples of a mechanical roller brush (e.g., roller brush 540 and roller brush 542) and examples of using a roller brush 542 to remove temporary bonding material 104 from a substrate 103, in accordance with embodiments of the present disclosure. Mechanical roller brushes made with a foam material such as polyvinyl alcohol (PVA) can be used for post-CMP scrubbing to remove particles from a surface of a semiconductor substrate. However, a foam brush may not remove temporary bonding material (e.g., temporary bonding adhesive, organic residue) that is adhered to a surface of a substrate. Advantageously, a roller brush 540 and roller brush 542, using a stiffer material than a foam material (e.g., CMP pad material) can be used remove temporary bonding material 104 from a substrate 103, in some embodiments of this disclosure.

In some embodiments, a roller brush 540 may comprise a roller 541 (e.g., cylinder, cylindrical structure) and a CMP pad material 505 attached to at least a portion of a surface of the roller 541. The CMP pad material may comprise any suitable material used in making a CMP pad. In some embodiments, CMP pad material may comprise polyurethane or polyethylene materials. The CMP pad material 505 or a CMP pad may be adhered to at least a portion of the surface of the roller 541. In some embodiments, a roller brush 542 may be similar to roller brush 540 except the CMP pad or CMP pad material 505 covers an entire surface of the roller 541. Although FIG. 5 shows a roller brush 542 being used to remove temporary bonding material 104 disposed on the substrate 103, in some embodiments the roller brush 540 may be used in place of roller brush 542 to remove temporary bonding material 104 disposed on the substrate 103.

A roller brush 542 may be used to remove temporary bonding material 104 on a substrate 103. The temporary bonding material 104 and substrate 103 is the same as described above in relation to FIGS. 1-3, and therefore the description of the features is omitted for brevity. The roller brush 542 may be held against the temporary bonding material 104 with some pressure (e.g., about 0.5-3 PSI) and rotated 507 or 555 to remove temporary bonding material 104. The substrate 103 may be attached to a tape 212 of a tape frame 210 and mounted on a holder 557 (e.g., chuck). In some embodiments, the holder 557 may be rotated 506 for a more even cleaning of the substrate 104.

In some embodiments, the mechanical roller brush (e.g., roller brush 540, 542) may be used for cleaning temporary bond residue of diced thin wafers as shown in inset 550. For example, roller brush 540 or 542 may be applied to a substrate (e.g., substrate 103 with temporary bonding material 104) after dicing (e.g., diced substrate, diced wafer, diced thin wafer) to remove temporary bonding material 554 on a diced substrate comprising a plurality of dies 553 with temporary bonding material 554. The roller brush 540, 542 may be held against the temporary bonding material 554 with some pressure (e.g., about 0.5-3 PSI) and rotated 507 or 555 to remove temporary bonding material 554. The substrate may be held by a tape 211 of a tape frame 210 and mounted on a holder 557 (e.g., chuck). In some embodiments, the holder 557 may be rotated 506 for a more even cleaning of the substrate.

A slurry 559 may be dispensed onto the substrate 103 by a dispensing tool 558 and may improve the results over those without a slurry 559 being used. The slurry 559 comprises abrasive particles. In some embodiments, water (e.g., DI water), with or without surfactants or detergent (e.g., cleaning solution) may be used instead of a slurry 559. The first substrate 103 may be mechanically scrubbed with water (e.g., deionized water), with or without surfactants or detergent, a slurry comprising abrasive particles, and/or any combination thereof using the roller brush (e.g., roller brush 540, roller brush 542). For example, water (e.g., deionized water), with or without surfactants or detergent, a slurry comprising abrasive particles, and/or any combination thereof may be dispensed while mechanically scrubbing the first substrate 103 with the roller brush.

A short plasma ashing process (e.g. about 1-2 minutes, less than about 1 minute, 2 minutes, 3 minutes, or 5 minutes, etc.) can optionally be combined with the mechanical scrubbing with the roller brush. The duration of the plasma ashing when used with mechanical scrubbing to remove temporary bonding material 104 may be much shorter than the duration of the plasma ashing for removing the temporary bonding material 104 without mechanical scrubbing. In some embodiments, the method may include plasma ashing the substrate 103 before and/or after mechanically scrubbing the first substrate 103 with the roller brush. In some embodiments, any suitable ashing process may be used (e.g., oxygen plasma ashing, fluorine plasma ashing, etc.).

Mechanically scrubbing the first substrate 103 using the roller brush (e.g., roller brush 540, roller brush 542) may remove the temporary bonding material 104 from a surface of the first substrate 103 (e.g., as shown in block 23 of FIG. 2A). In some embodiments, mechanically scrubbing the first substrate 103 using the roller brush may remove contaminants or particles from a surface of the first substrate 103. In some embodiments, mechanically scrubbing the first substrate 103 using the roller brush may provide a planarized surface of the first substrate 103. For example, a recess of conductive features disposed in a dielectric layer of the substrate may be controlled using mechanical scrubbing with the roller brush.

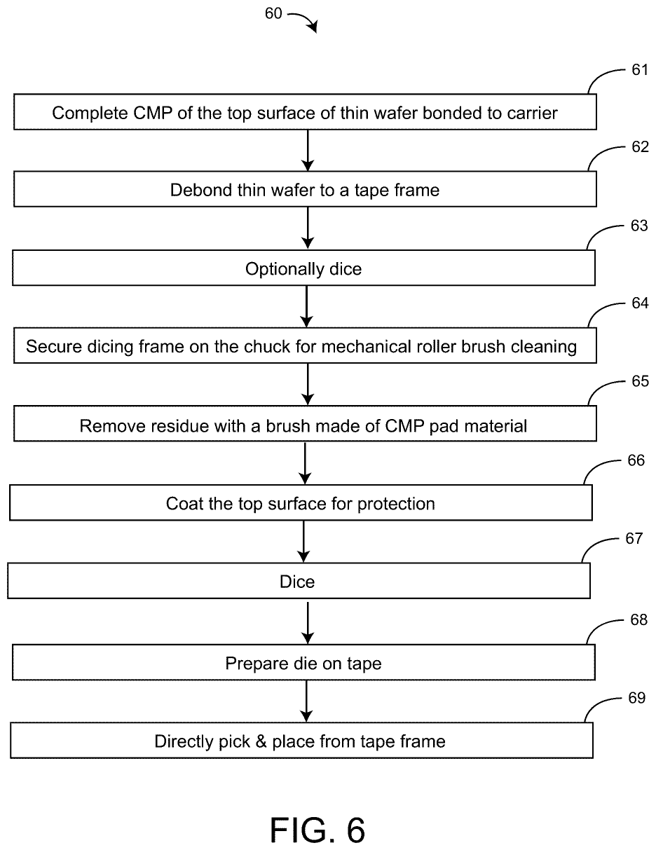

FIG. 6 shows an example method 60, in accordance with embodiments of the present disclosure. In some embodiments, the method 60 may be used in relation to the apparatus shown in FIG. 5.

At block 61, the method 60 may include completing CMP of the top surface of a thin wafer bonded to a carrier. For example, a thin wafer (e.g., substrate 103) may be bonded to a carrier (e.g., substrate 205) using temporary bonding adhesive (e.g., temporary bonding layer 214 as shown in block 20 of FIG. 2A). A bottom surface of the thin wafer (e.g., second surface of substrate 103) may be attached to a surface of the carrier and a top surface (e.g., first surface of substrate 103) may be exposed. The top surface of the wafer may be chemically mechanically polished.

At block 62, the method 60 may include debonding a thin wafer to a tape frame. For example, the thin wafer (e.g., substrate 103) may be debonded from the carrier wafer (e.g., substrate 205) and attached to the tape 211 of the tape frame 210. In some embodiments, a majority or bulk of the temporary bonding adhesive can be removed by wet chemical cleaning or mechanical peeling. Temporary bonding material 104 (e.g., temporary bonding material residue) may remain or be disposed on a surface of the thin wafer after debonding. In some embodiments, the method 60 may further include optionally removing the bulk of the temporary bond residue by solvent clean or mechanical peeling (e.g., similar to block 43 of FIG. 4). The method 60 may include removing a larger portion of temporary bond residue (e.g., temporary bonding material 104) using solvent clean or mechanical peeling. A smaller portion of the temporary bond residue may remain on a surface of the thin wafer (e.g., first surface of substrate 103).

At block 63, the method 60 may include optionally dicing the thin wafer. The method may include dicing the thin wafer (e.g., substrate 103 and temporary bonding material 104) as shown in the inset 550 of FIG. 5. In some embodiments, the thin wafer (e.g., substrate 103) is not diced as shown in FIG. 5.

At block 64, the method 60 may include securing dicing frame on the chuck for

mechanical roller brush cleaning. For example, a thin wafer (e.g., substrate 103) may be attached to a tape frame 210 (e.g., dicing frame via tape 211), and the tape frame 210 (e.g., dicing frame) may be secured on a holder 557 (e.g., chuck) for mechanical roller brush cleaning.

At block 65, the method 60 may include removing the residue (e.g., temporary bonding material 104) with a brush made of CMP pad material (e.g., roller brush 540, 542). The method may include mechanically scrubbing the substrate 103 using a roller brush 540, 542 as described in relation to FIG. 5. The roller brush 540, 542 may comprise a CMP pad or CMP pad material 505 attached to a roller 541. Removing the residue with the brush made of CMP pad material may be performed with a slurry, water (e.g., DI water), with or without surfactants or detergent (e.g., cleaning solution). In some embodiments, mechanical brushing may be combined with plasma ashing and may improve results (e.g., removal of temporary bonding material, contaminants, etc.). A short plasma ashing process (e.g. about 1-2 minutes, less than about 1 minute, 2 minutes, 3 minutes, or 5 minutes, etc.) can optionally be combined with the mechanical scrubbing with the roller brush. The duration of the plasma ashing when used with mechanical scrubbing to remove temporary bonding material 104 may be much shorter than the duration of the plasma ashing for removing the temporary bonding material 104 without mechanical scrubbing. In some embodiments, the method may include plasma ashing the substrate 103 before and/or after mechanically scrubbing the first substrate 103 with the roller brush (e.g., at block 65). In some embodiments, any suitable ashing process may be used (e.g., oxygen plasma ashing, fluorine plasma ashing, etc.).

At block 66, the method 60 may include coating the top surface for protection. Block 66 may be similar to block 46 of FIG. 4. For example, the top surface (e.g., first surface of substrate 103) cleaned at block 65 may be coated with photoresist (e.g., protective coating 212 as shown in block 24 of FIG. 2B) to protect the top surface (e.g., surface that is used later for bonding) during dicing the thin wafer (e.g., substrate 103). In some embodiments, the method 60 may include dicing the substrate at block 63 and may not include coating the top surface for protection at block 66.

At block 67, the method 60 may include dicing the substrate. Block 67 may be similar to block 47 of FIG. 4. For example, the thin wafer (e.g., substrate 103) with the protective coating may be diced (e.g., as shown in block 28 of FIG. 2B). In some embodiments, the method 60 may not include optionally dicing the substrate at block 63, and the method 60 may include coating the top surface for protection at block 66 and dicing the substrate at block 67. In some embodiments, the method includes dicing the substrate at block 63 and may not include coating the top surface for protection at block 66 and dicing the substrate at block 67.

At block 68, the method 60 may include die on tape preparation. For example, the preparation may be preparing the surface to be bonded. The method 60 may include rinsing with DI water and optionally activating the surface to be bonded. Examples of preparing a surface to be bonded can be found in the description of FIGS. 7A-7B. In some embodiments, the method 60 may not include optionally dicing the substrate at block 63, and the method 60 may include coating the top surface for protection at block 66, dicing the substrate at block 67, and cleaning off the protective coating and preparing the surface to be bonded at block 68. The method 60 may include stripping the protective coating, rinsing with DI water, and optionally activating the surface to be bonded. In some embodiments, the method 60 includes dicing the substrate at block 63 and may not include coating the top surface for protection at block 66, dicing the substrate at block 67, and cleaning off the protective coating at block 68.

At block 69, the method may include directly picking and placing dies from the tape frame. For example, a cleaned die (e.g., die 553 with temporary bonding material 554 removed) may be picked from the tape 211 and placed on another substrate (e.g., substrate to be directly bonded, hybrid bonded).

In some embodiments, a method includes using a mechanical roller brush (e.g., roller brush 540, 542) made with CMP pad material 505 to remove contaminants from a debonded substrate for use in hybrid bonding. In some embodiments, the mechanical roller brush may be applied to a substrate 103 prior to dicing as shown in FIG. 5, and a protective coating may be applied to the cleaned wafer and then diced (e.g., method 60 does not include block 63, and includes blocks 46-49 of method 40 in place of blocks 66-67).

In some embodiments, CMP of a substrate (e.g., mechanically scrubbing using a CMP pad or CMP material as shown in FIGS. 1, 3, and 5) may be a final step of DBI surface fabrication. CMP may be used to control conductive feature (e.g., metal, Cu) recess and may leave the surface pristine for bonding. CMP may be used to remove temporary bond residue on substrates (e.g., thin wafers) after debonding, including organic and inorganic residues. CMP may be used to remove temporary bond residue on diced substrates (e.g., thin die after dicing, diced wafer). In some embodiments, a protective layer may not be used during dicing if the temporary bond residue adheres to the surface and remains on the surface after dicing. In some embodiments, CMP may be combined with ashing and may improve results.

In some embodiments, CMP (e.g., mechanically scrubbing using a CMP pad or CMP material as shown in FIGS. 1, 3, and 5) may produce high quality bonding surfaces for thin wafers and/or dies for DBI bonding (e.g., particle free surfaces and well controlled Cu recess prior to bonding). The cleaned substrates (e.g., thin wafers and/or dies) may be used for 3D stacking with DBI bonding.

CMP (e.g., mechanically scrubbing using a CMP pad or CMP material as shown in FIGS. 1, 3, and 5) may be used to remove all types of temporary bond residue. CMP may be combined with other methods and used as the final step for Cu recess control in the cases that a thick organic coating needs to be removed. Using CMP alone may cause the CMP pad to be loaded. A CMP pad may be coated with a slurry containing abrasive particles to actively remove material such as a thick organic coating, conductive features, and/or any suitable material of a semiconductor substrate (e.g., for cleaning a surface of a thick organic coating, Cu recess control, etc.).

A challenge in handling a thin wafer (e.g., substrate, die) is to prevent breakage of the thin wafer during a CMP process. Embodiments in this present disclosure may help address the challenges of handling a thin wafer during the CMP process by using a secondary carrier (e.g., using a second substrate 101 to support a first substrate 103 in embodiments related to FIGS. 1 and 2A-2B), using a tape frame adaptor for CMP or using an orbital CMP configuration with a particular head for holding the dicing frame (e.g., using CMP head 331 of FIG. 3), using mechanical roller brushing with CMP pad material (e.g., using roller brushes 540, 542 of FIG.

5), and using a drip slurry over the wafer (e.g., using dispensing tool 558 of FIG. 5). The mechanical roller brushing with CMP pad material may be performed on a thin wafer or a diced thin wafer on a tape frame held by a dicing frame support chuck (e.g., holder 557 of FIG. 5).

In some embodiments, the method includes cleaning of wafer surface by CMP (e.g., mechanically scrubbing using a CMP pad or CMP material as shown in FIGS. 1, 3, and 5) for wafers thinner than 100 um, 50 um, 20 um. In some embodiments, the method includes CMP of thin wafers supported by a dicing frame (e.g., mechanically scrubbing as shown in FIG. 3). In some embodiments, the method includes cleaning of thin die supported by a dicing tape by mechanical brushing (e.g., mechanically scrubbing as shown in FIG. 5).

In some embodiments, a cleaning apparatus includes a CMP head for securing the tape frame (e.g., CMP head 331 of FIG. 3). In some embodiments, a cleaning apparatus includes a roller brush cleaning station with a roller brush made of CMP pad material and CMP slurry (e.g., roller brush 540, 542 and slurry 559 of FIG. 5). In some embodiments, a CMP head to hold the dicing frame may be used (e.g., CMP head 331 of FIG. 3).

In some embodiments, CMP (e.g., mechanically scrubbing using a CMP pad or CMP material as shown in FIGS. 1, 3, and 5) may have advantages over wet chemical clean or dry clean (ashing). A wet chemical clean may require special equipment, may use hazardous solvent, can potentially attack metal (e.g., copper), and may not be particle free. A dry etch may have compatibility with dicing tape, may oxidize metal (e.g., copper), may change metal (e.g., copper) recess, and may not be particle free. Using CMP may leverage equipment for a DBI layer fab, may not use hazardous solvent, may not have a compatibility issue with dicing tape, may well control metal (e.g., copper) recess, and may be particle free or smaller particle sizes with controlled metal (e.g., copper) recess.

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 708a and/or 708b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, and U.S. patent application Ser. No. 18/391, 173, filed Dec. 20, 2023, the entire contents of each of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

FIGS. 7A and 7B schematically illustrate cross-sectional side views of first and second elements 702, 704 prior to and after, respectively, a process for forming a directly bonded structure, and more particularly a hybrid bonded structure, according to some embodiments. In FIG. 7B, a bonded structure 700 comprises the first and second elements 702 and 704 that are directly bonded to one another at a bond interface 718 without an intervening adhesive. Conductive features 706a of a first element 702 may be electrically connected to corresponding conductive features 706b of a second element 704. In the illustrated hybrid bonded structure 700, the conductive features 706a are directly bonded to the corresponding conductive features 706b without intervening solder or conductive adhesive.

The conductive features 706a and 706b of the illustrated embodiment are embedded in, and can be considered part of, a first bonding layer 708a of the first element 702 and a second bonding layer 708b of the second element 704, respectively. Field regions of the bonding layers 708a, 708b extend between and partially or fully surround the conductive features 706a, 706b. The bonding layers 708a, 708b can comprise layers of non-conductive materials suitable for direct bonding, as described above, and the field regions are directly bonded to one another without an adhesive. The non-conductive bonding layers 708a, 708b can be disposed on respective front sides 714a, 714b of base substrate portions 710a, 710b.

The first and second elements 702, 704 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 702, 704, and back-end-of-line (BEOL) interconnect layers over such semiconductor portions. The bonding layers 708a, 708b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 710a, 710b, and can electrically communicate with at least some of the conductive features 706a, 706b. Active devices and/or circuitry can be disposed at or near the front sides 714a, 714b of the base substrate portions 710a, 710b, and/or at or near opposite backsides 716a, 716b of the base substrate portions 710a, 710b. In other embodiments, the base substrate portions 710a, 710b may not include active circuitry, but may instead comprise dummy substrates, passive interposers, passive optical elements (e.g., glass substrates, gratings, lenses), etc. The bonding layers 708a, 708b are shown as being provided on the front sides of the elements, but similar bonding layers can be additionally or alternatively provided on the back sides of the elements.

In some embodiments, the base substrate portions 710a, 710b can have significantly different coefficients of thermal expansion (CTEs), and bonding elements that include such different based substrate portions can form a heterogenous bonded structure. The CTE difference between the base substrate portions 710a and 710b, and particularly between bulk semiconductor (typically single crystal) portions of the base substrate portions 710a, 710b, can be greater than 5 ppm/° C. or greater than 10 ppm/° C. For example, the CTE difference between the base substrate portions 710a and 710b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 710a, 710b can comprise optoelectronic single crystal materials, including perovskite materials, that are useful for optical piezoelectric or pyroelectric applications, and the other of the base substrate portions 710a, 710b comprises a more conventional substrate material. For example, one of the base substrate portions 710a, 710b comprises lithium tantalate (LiTaO₃) or lithium niobate (LiNbO₃), and the other one of the base substrate portions 710a, 710b comprises silicon (Si), quartz, fused silica glass, sapphire, or a glass. In other embodiments, one of the base substrate portions 710a, 710b comprises a III-V single semiconductor material, such as gallium arsenide (GaAs) or gallium nitride (GaN), and the other one of the base substrate portions 710a, 710b can comprise a non-III-V semiconductor material, such as silicon (Si), or can comprise other materials with similar CTE, such as quartz, fused silica glass, sapphire, or a glass. In still other embodiments, one of the base substrate portions 710a, 710b comprises a semiconductor material and the other of the base substrate portions 710a, 710b comprises a packaging material, such as a glass, organic or ceramic substrate.

In some arrangements, the first element 702 can comprise a singulated element, such as a singulated integrated device die. In other arrangements, the first element 702 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 704 can comprise a singulated element, such as a singulated integrated device die. In other arrangements, the second element 704 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 702, 704 are shown, any suitable number of elements can be stacked in the bonded structure 700. For example, a third element (not shown) can be stacked on the second element 704, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 702. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 708a, 708b, the bonding layers 708a, 708b can be prepared for direct bonding. Non-conductive bonding surfaces 712a, 712b at the upper or exterior surfaces of the bonding layers 708a, 708b can be prepared for direct bonding by polishing, for example, by chemical mechanical polishing (CMP). The roughness of the polished bonding surfaces 712a, 712b can be less than 30 Å rms. For example, the roughness of the bonding surfaces 712a and 712b can be in a range of about 0.1 Å rms to 15 Å rms, 0.5 Å rms to 10 Årms, or 1 Årms to 5 Å rms. Polishing can also be tuned to leave the conductive features 706a, 706b recessed relative to the field regions of the bonding layers 708a, 708b.

Preparation for direct bonding can also include cleaning and exposing one or both of the bonding surfaces 712a, 712b to a plasma and/or etchants to activate at least one of the surfaces 712a, 712b. In some embodiments, one or both of the surfaces 712a, 712b can be terminated with a species after activation or during activation (e.g., during the plasma and/or etch processes). Without being limited by theory, in some embodiments, the activation process can be performed to break chemical bonds at the bonding surface(s) 712a, 712b, and the termination process can provide additional chemical species at the bonding surface(s) 712a, 712b that alters the chemical bond and/or improves the bonding energy during direct bonding. In some embodiments, the activation and termination are provided in the same step, e.g., a plasma to activate and terminate the surface(s) 712a, 712b. In other embodiments, one or both of the bonding surfaces 712a, 712b can be terminated in a separate treatment to provide the additional species for direct bonding. In various embodiments, the terminating species can comprise nitrogen. For example, in some embodiments, the bonding surface(s) 712a, 712b can be exposed to a nitrogen-containing plasma. Other terminating species can be suitable for improving bonding energy, depending upon the materials of the bonding surfaces 712a, 712b. Further, in some embodiments, the bonding surface(s) 712a, 712b can be exposed to fluorine. For example, there may be one or multiple fluorine concentration peaks at or near a bond interface 718 between the first and second elements 702, 704. Typically, fluorine concentration peaks occur at interfaces between material layers. Additional examples of activation and/or termination treatments may be found in U.S. Pat. Nos. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 700, the bond interface 718 between two non-conductive materials (e.g., the bonding layers 708a, 708b) can comprise a very smooth interface with higher nitrogen (or other terminating species) content and/or fluorine concentration peaks at the bond interface 718. In some embodiments, the nitrogen and/or fluorine concentration peaks may be detected using various types of inspection techniques, such as SIMS techniques. The polished bonding surfaces 712a and 712b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 708a and 708b can be directly bonded to one another without an adhesive. In some embodiments, the elements 702, 704 are brought together at room temperature, without the need for application of a voltage, and without the need for application of external pressure or force beyond that used to initiate contact between the two elements 702, 704. Contact alone can cause direct bonding between the non-conductive surfaces of the bonding layers 708a, 708b (e.g., covalent dielectric bonding). Subsequent annealing of the bonded structure 700 can cause the conductive features 706a, 706b to directly bond.

In some embodiments, prior to direct bonding, the conductive features 706a, 706b are recessed relative to the surrounding field regions, such that a total gap between opposing contacts after dielectric bonding and prior to anneal is less than 15 nm, or less than 10 nm. Because the recess depths for the conductive features 706a and 706b can vary across each element, due to process variation, the noted gap can represent a maximum or an average gap between corresponding conductive features 706a, 706b of two joined elements (prior to anneal). Upon annealing, the conductive features 706a and 706b can expand and contact one another to form a metal-to-metal direct bond.

During annealing, the conductive features 706a, 706b (e.g., metallic material) can expand while the direct bonds between surrounding non-conductive materials of the bonding layers 708a, 708b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 706a, 706b can comprise discrete pads, contacts, electrodes, or traces at least partially embedded in the non-conductive field regions of the bonding layers 708a, 708b. In some embodiments, the conductive features 706a, 706b can comprise exposed contact surfaces of TSVs (e.g., through silicon vias).

As noted above, in some embodiments, in the elements 702, 704 of FIG. 1A prior to direct bonding, portions of the respective conductive features 706a and 706b can be recessed below the non-conductive bonding surfaces 712a and 712b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 706a, 706b or to average depths of the recesses relative to local non-conductive field regions. Even for an individual conductive feature 706a, 706b, the vertical recess can vary across the feature, and so can be measured at or near the lateral middle or center of the cavity in which a given conductive feature 706a, 706b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 706a, 706b across the direct bond interface 718 (e.g., small or fine pitches for regular arrays).

In some embodiments, a pitch p of the conductive features 706a, 706b, such as

conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 706a and 706b to one of the lateral dimensions (e.g., a diameter) of the bonding pad is less than is less than 20, or less than 10, or less than 5, or less than 3 and sometimes desirably less than 2. In various embodiments, the conductive features 706a and 706b and/or traces can comprise copper or copper alloys, although other metals may be suitable, such as nickel, aluminum, or alloys thereof. The conductive features disclosed herein, such as the conductive features 706a and 706b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 702, 704, as shown, the orientations of one or more conductive features 706a, 706b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 706b in the bonding layer 708b (and/or at least one internal conductive feature, such as a BEOL feature) of the upper element 704 may be tapered or narrowed upwardly, away from the bonding surface 712b. By way of contrast, at least one conductive feature 706a in the bonding layer 708a (and/or at least one internal conductive feature, such as a BEOL feature) of the lower element 702 may be tapered or narrowed downwardly, away from the bonding surface 712a. Similarly, any bonding layers (not shown) on the backsides 716a, 716b of the elements 702, 704 may taper or narrow away from the backsides, with an opposite taper orientation relative to front side conductive features 706a, 706b of the same element.

As described above, in an anneal phase of hybrid bonding, the conductive features 706a, 706b can expand and contact one another to form a metal-to-metal direct bond. In some embodiments, the materials of the conductive features 706a, 706b of opposite elements 702, 704 can interdiffuse during the annealing process. In some embodiments, metal grains grow into each other across the bond interface 718. In some embodiments, the metal is or includes copper, which can have grains oriented along the 711 crystal plane for improved copper diffusion across the bond interface 718. In some embodiments, the conductive features 706a and 706b may include nanotwinned copper grain structure, which can aid in merging the conductive features during anneal. There is substantially no gap between the non-conductive bonding layers 708a and 708b at or near the bonded conductive features 706a and 706b. In some embodiments, a barrier layer may be provided under and/or laterally surrounding the conductive features 706a and 706b (e.g., which may include copper). In other embodiments, however, there may be no barrier layer under the conductive features 706a and 706b.

The embodiments discussed above are intended to be illustrative and not limiting. One skilled in the art would appreciate that individual aspects of the apparatuses and methods discussed herein may be omitted, modified, combined, and/or rearranged without departing from the scope of the disclosure.

1. A method comprising:
providing a first substrate having a thickness of less than about 400 um, the first substrate comprising a first surface and a second surface opposite the first surface, wherein a temporary bonding material is disposed on the second surface of the first substrate; and
attaching the first substrate to a second substrate such that the first surface of the first substrate is attached to a surface of the second substrate; and
mechanically scrubbing the temporary bonding material disposed on the second surface of the first substrate with a chemical mechanical polishing (CMP) pad to remove the temporary bonding material from the second surface of the first substrate.

2. The method of claim 1, further comprising using deionized water, with or without surfactants or detergent, and/or a combination thereof without a slurry comprising abrasive particles while mechanically scrubbing.

3. The method of claim 1, further comprising using a slurry comprising abrasive particles while mechanically scrubbing.

4. The method of claim 1, further comprising rotating the CMP pad in an orbital motion while mechanically scrubbing.

5. The method of claim 1, further comprising rotating the first substrate while mechanically scrubbing.

6. The method of claim 1, further comprising before or after mechanically scrubbing the temporary bonding material disposed on the second surface of the first substrate, plasma ashing the first substrate.

7. The method of claim 1, wherein:
prior to mechanically scrubbing, the first substrate is bonded to a third substrate with temporary bonding adhesive;
the method further comprises prior to mechanically scrubbing, debonding the first substrate from the third substrate; and
the temporary bonding material disposed on the second surface of the first substrate comprises temporary bonding adhesive residue.

8. The method of claim 1, further comprising:
disposing a protective coating on a mechanically scrubbed second surface of the first substrate;
attaching the first substrate to a temporary carrier such that the protective coating on the second surface of the first substrate is attached to a surface of the temporary carrier; and
removing the second substrate from the first substrate.

9. The method of claim 8, wherein:
attaching the first substrate to the second substrate comprises attaching the first substrate to the second substrate using double sided tape; and
removing the second substrate from the first substrate comprises removing the double sided tape and the second substrate from the first surface of the first substrate.

10. The method of claim 8, the method further comprising:
flipping the first substrate such that the first surface of the first substrate is attached to the surface of the temporary carrier; and
dicing the first substrate.

11. The method of claim 1, wherein the thickness of the first substrate is less than about 100 um.

12. The method of claim 1, wherein the thickness of the first substrate is less than about 50 um.

13. The method of claim 1, wherein the thickness of the first substrate is less than about 20 um.

14. The method of claim 1, wherein the temporary bonding material comprises inorganic material.

15. The method of claim 1, wherein the temporary bonding material comprises organic material.

16. The method of claim 1, wherein the temporary bonding material comprises at least one of: an ultraviolet (UV) cured polymer, a thermal plastic polymer, or a polyimide.

17. A apparatus comprising:
a holder for securing a tape frame; and
an air pressure chamber capable of applying pressure to a substrate disposed on a tape held by the tape frame against a CMP pad.

18. The apparatus of claim 17, wherein the air pressure chamber is capable of applying a pressure between about 0.5 PSI to 3 PSI.

19. An apparatus comprising:
a roller; and
chemical mechanical polishing (CMP) pad material attached to the roller, wherein the roller is covered, at least partially, by the CMP pad material.

20. The apparatus of claim 19, wherein the apparatus further comprises:
a holder capable of holding a substrate against the CMP pad material attached to the roller; and
a dispensing mechanism to deliver DI water, surfactants, detergent, or a CMP slurry to the substrate.
